(19) United States
(12) Patent Application Publication
(10) Pub. No.: US 2026/0148759 A1
(43) Pub. Date: May 28, 2026

(54) MEMORY DEVICE AND OPERATING METHOD OF MEMORY DEVICE

(71) Applicant: SK hynix Inc., Gyeonggi-do (KR)

(72) Inventor: Do Young KIM, Gyeonggi-do (KR)

(21) Appl. No.: 19/192,346

(22) Filed: Apr. 29, 2025

(30) Foreign Application Priority Data
Nov. 28, 2024 (KR) 10-2024-0173225

(51) Int. Cl. G11C 8/08; G11C 7/22

(52) U.S. Cl. CPC G11C 8/08; G11C 7/22

(57) ABSTRACT

An operating method of a memory device, in a program operation, applies a first program pass voltage to program non-selected word lines of first word lines and second word lines, the first and second word lines coupled to first memory cells and second memory cells of a string, respectively, and applies a second program pass voltage to a first intermediate dummy word line coupled to a first intermediate dummy memory cell, among the first intermediate dummy memory cell and a second intermediate dummy memory cell coupled between the first memory cells and the second memory cells in the string.

### CROSS-REFERENCES TO RELATED APPLICATION

The present application claims priority under 35 U.S.C. § 119(a) to Korean patent application number 10-2024-0173225 filed on Nov. 28, 2024, which is incorporated herein by reference in its entirety.

### BACKGROUND

### 1. Technical Field

Various embodiments of the present disclosure generally relate to a memory device and an operating method of the memory device.

### 2. Related Art

As memory technology evolves, the demand for data processing speed and larger storage capacity continues to rise. Plug stacking technology can increase storage capacity per unit area and reduce conduction paths between layers, thereby enhancing data access speed. However, plug stacking technology comes with high technical requirements, and misalignment or poor contact of the plugs can cause failures in memory cell operations. Therefore, while process precision can be improved or advanced defect detection techniques can be developed, there is a need for more efficient and effective ways to mitigate the issues arising from plug stacking defects.

### SUMMARY

In an embodiment of the present disclosure, an operating method of a memory device may include in a program operation, applying a first program pass voltage to program non-selected word lines of first word lines and second word lines, the first and second word lines coupled to first memory cells and second memory cells of a string, respectively, and applying a second program pass voltage to a first intermediate dummy word line coupled to a first intermediate dummy memory cell, among the first intermediate dummy memory cell and a second intermediate dummy memory cell coupled to the first intermediate dummy word line and a second intermediate dummy word line, respectively, between the first memory cells and the second memory cells in the string, wherein the second program pass voltage is less than the first program pass voltage.

In an embodiment of the present disclosure, a memory device may include a string, a control circuit, and a peripheral circuit. The string may include a first region formed on a first plug and a second region formed on a second plug stacked on the first plug, the first region may include a first intermediate dummy memory cell coupled to a first intermediate dummy word line and first memory cells coupled to first word lines, the second region may include a second intermediate dummy memory cell coupled to a second intermediate dummy word line and second memory cells coupled to second word lines, the first and second intermediate dummy memory cells may be adjacent to the first region and the second region, and the first and second intermediate dummy word lines may be coupled to a common intermediate dummy word line. The control circuit may be configured to control one or more operations on one or more memory cells of the string. The peripheral circuit may be configured to generate operating voltages for the one or more operations, and may be configured to apply the operating voltages to the first and second word lines and the common intermediate dummy word line.

### BRIEF DESCRIPTION OF THE DRAWINGS

FIG. 1 is a block diagram illustrating a memory device according to an embodiment of the present disclosure.

FIG. 2 is a circuit diagram illustrating a string included in a memory cell array according to an embodiment of the present disclosure.

FIGS. 3A and 3B are simplified cross-sectional diagrams illustrating the vicinity of the boundary BD1 between a first region and a second region according to an embodiment of the present disclosure.

FIGS. 4A to 4C are diagrams illustrating operating voltages applied to the vicinity of the boundary of the string of FIG. 2.

FIG. 5 is a diagram illustrating a string according to an embodiment of the present disclosure.

FIGS. 6A to 6C are diagrams illustrating operating voltages applied to the vicinity of the boundary of the string of FIG. 5.

FIG. 7 is a diagram illustrating a string according to an embodiment of the present disclosure.

FIGS. 8A to 8C are diagrams illustrating operating voltages applied to the vicinity of the boundary of the string of FIG. 7.

FIG. 9 is a diagram illustrating a string according to an embodiment of the present disclosure.

FIGS. 10A to 10C are diagrams illustrating operating voltages applied to the vicinity of the boundary of the string of FIG. 9.

FIG. 11 is a flowchart illustrating a method of operating a memory device according to an embodiment of the present disclosure.

### DETAILED DESCRIPTION

Hereinafter, embodiments of the present disclosure will be described in more detail with reference to the accompanying drawings.

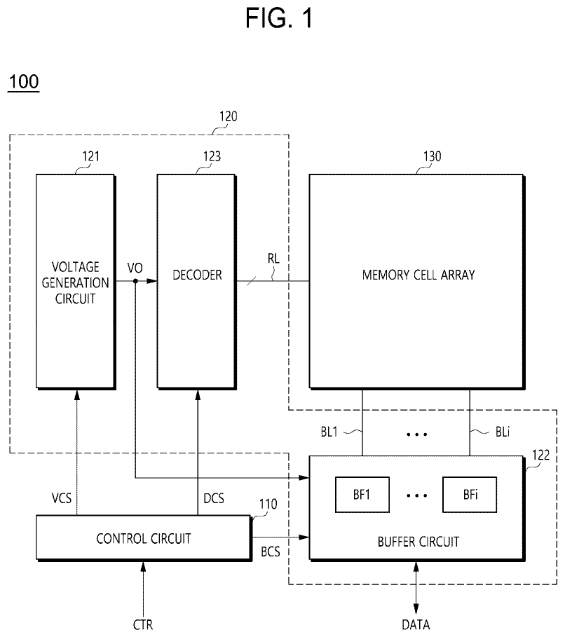

FIG. 1 is a block diagram illustrating a memory device 100 according to an embodiment of the present disclosure.

Referring to FIG. 1, the memory device 100 may operate in response to a control signal CTR from an external controller. The memory device 100 may store data DATA received from the controller by performing a program operation, and may output the stored data DATA to the controller by performing a read operation.

The memory device 100 may include a control circuit 110, a peripheral circuit 120, and a memory cell array 130. The peripheral circuit 120 may include a voltage generation circuit 121, a buffer circuit 122, and a decoder 123.

The control circuit 110 may control operation of the voltage generation circuit 121, the buffer circuit 122, and the decoder 123 to perform memory cell operations, such as program operations, read operations, erase operations, and the like, under control of the controller. For example, to control the voltage generation circuit 121, the control circuit 110 may generate a voltage control signal VCS and output the voltage control signal VCS to the voltage generation circuit 121. To control the buffer circuit 122, the control circuit 110 may generate a buffer control signal BCS and output the buffer control signal BCS to the buffer circuit 122. To control the decoder 123, the control circuit 110 may generate a decoder control signal DCS and output the decoder control signal DCS to the decoder 123.

The peripheral circuit 120 may store data in the memory cell array 130 and read data from the memory cell array 130 under control of the control circuit 110.

The voltage generation circuit 121 may generate various operating voltages VO in response to the voltage control signal VCS, and may pass the operating voltages VO to the decoder 123 and the buffer circuit 122.

The buffer circuit 122 may be coupled to the memory cell array 130 through bit lines BL1 to BLi. The buffer circuit 122 may include sub-buffers BF1 to BFi coupled to the bit lines BL1 to BLi, respectively. The sub-buffers BF1 to BFi may be coupled with memory cells included in the memory cell array 130 through the bit lines BL1 to BLi. The sub-buffers BF1 to BFi may receive and store data to be stored in the memory cells from the controller. The sub-buffers BF1 to BFi may store data read from the memory cells for output to the controller. The sub-buffers BF1 to BFi may operate simultaneously in response to the buffer control signal BCS, such that the memory cells coupled with the bit lines BL1 to BLi, respectively, may be accessed simultaneously.

The decoder 123 may be coupled to the memory cell array 130 through row lines RL. The decoder 123 may apply operating voltages VO to the row lines RL in response to the decoder control signal DCS. The row lines RL may include a drain selection line, intermediate dummy word lines, word lines, and a source selection line, which will be described later. The operating voltages VO may include a program voltage, a program pass voltage, a read voltage, a read pass voltage, an erase voltage, a gate voltage, and the like, which will be described later.

The memory cell array 130 may include memory cells in which data DATA is stored. The memory cells may be selectively accessed through the row lines RL and the bit lines BL1 to BLi.

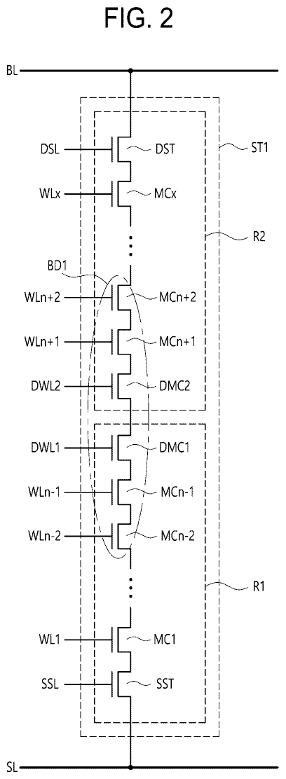

FIG. 2 is a circuit diagram illustrating a string ST1 included in the memory cell array 130 according to an embodiment of the present disclosure.

Referring to FIG. 2, the string ST1 may be coupled between a bit line BL and a source line SL. The string ST1 may include a first region R1 and a second region R2.

The first region R1 may include a source selection transistor SST coupled to the source line SL, a first intermediate dummy memory cell DMC1, and first memory cells MC1 to MCn−1 coupled in series between the source selection transistor SST and the first intermediate dummy memory cell DMC1. The second region R2 may include a second intermediate dummy memory cell DMC2 coupled to the first intermediate dummy memory cell DMC1, a drain selection transistor DST coupled with the bit line BL, and second memory cells MCn+1 to MCx coupled in series between the second intermediate dummy memory cell DMC2 and the drain selection transistor DST.

The first memory cells MC1 to MCn−1 may be coupled to first word lines WL1 to WLn−1, respectively. The second memory cells MCn+1 to MCx may be coupled to second word lines WLn+1 to WLx, respectively. The first and second intermediate dummy memory cells DMC1, DMC2 may be coupled to first and second intermediate dummy word lines DWL1, DWL2, respectively. The source selection transistor SST may be coupled to a source selection line SSL. The drain selection transistor DST may be coupled to a drain selection line DSL.

The first region R1 and the second region R2 may include a boundary BD1. The vicinity of the boundary BD1 may include the first and second intermediate dummy memory cells DMC1, DMC2 and neighboring memory cells adjacent thereto (e.g., MCn−2, MCn−1, MCn+1, MCn+2). The number of neighboring memory cells shown as being included in the vicinity of the boundary BD1 are illustrated as an example and other numbers of neighboring memory cells may be used.

In an embodiment, the first region R1 may further include one or more dummy memory cells coupled in series between the source selection transistor SST and the memory cell MC1. The second region R2 may further include one or more dummy memory cells coupled in series between the drain selection transistor DST and the memory cell MCx.

The bit line BL may be any of the bit lines BL1 to BLi of FIG. 1. A plurality of strings may be coupled between the bit lines BL1 to BLi and the source line SL in a manner similar to the string ST1. The plurality of strings coupled to the bit lines BL1 to BLi may be coupled in common to the drain selection line DSL, the first word lines WL1 to WLn−1, the second word lines WLn+1 to WLx, the first and second intermediate dummy word lines DWL1 and DWL2, and the source selection line SSL.

A target memory cell may be any of the first and second memory cells MC1 to MCn−1, MCn+1 to MCx on which a memory cell operation is to be performed. A target word line may be a word line to which the target memory cell is coupled among the first and second word lines WL1 to WLn−1, WLn+1 to WLx. A program non-selected word line may be a word line that is not a target word line of the program operation among the first and second word lines WL1 to WLn−1, WLn+1 to WLx. The read non-selected word lines may be a word line that is not a target word line of a read operation among the first and second word lines WL1 to WLn−1, WLn+1 to WLx.

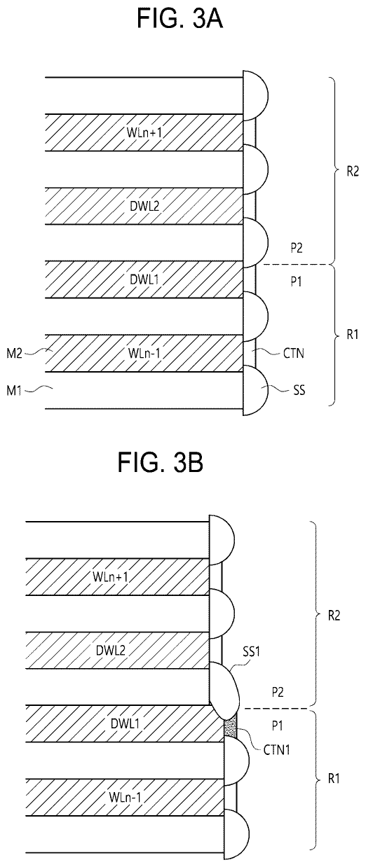

FIGS. 3A and 3B are simplified cross-sectional diagrams illustrating the vicinity of the boundary BD1 between the first region R1 and the second region R2 according to an embodiment of the present disclosure.

Referring to FIG. 3A, the second region R2 formed on a second plug P2 may be stacked on top of the first region R1 formed on a first plug P1. In each of the first region R1 and the second region R2, an insulator M1 and a conductor M2 may be alternately stacked. Each of the first plug P1 and the second plug P2 may include a charge trap structure CTN located on a side of each conductor M2 and a separation structure SS located on a side of each insulator M1. The separation structure SS may separate neighboring charge trap structures CTNs. The insulator M1 and/or the separation structure SS may include an oxide, silicon oxide, or the like.

A conductor M2 located at the uppermost end of the first region R1 may function as the first intermediate dummy word line DWL1. At the bottommost end of the second region R2, an insulator M1 stacked on top of the first intermediate dummy word line DWL1 is located, and a conductor M2 located on top of the insulator M1 may function as the second intermediate dummy word line DWL2. The conductors M2 other than the first and second intermediate dummy word lines DWL1, DWL2 may function as the word lines WLn−1, WLn+1. Each charge trap structure CTN may be included in each memory cell. The overlay of the first plug P1 and the second plug P2 may be normal, which means that the first plug P1 and the second plug P2 are precisely aligned as shown in FIG. 3A.

Referring to FIG. 3B, the overlay may be abnormal because the first plug P1 and the second plug P2 are not precisely aligned. In this case, the separation structure SS1 may be abnormally formed at the boundary between the first region R1 and the second region R2. Accordingly, the charge trap structure CTN1 adjacent to the first intermediate dummy word line DWL1 might not be properly formed, and the first intermediate dummy memory cell DMC1 formed by the charge trap structure CTN1 may be vulnerable to voltage stress. As a result, failures in memory cell operation may occur.

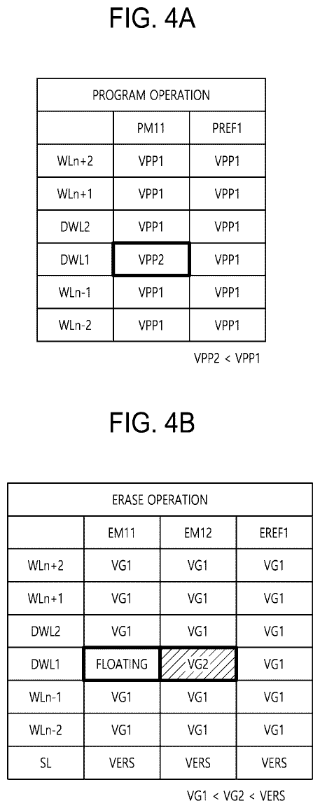

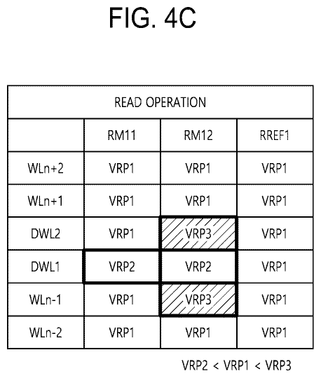

FIGS. 4A to 4C are diagrams illustrating operating voltages applied to the vicinity of the boundary BD1 of the string ST1 of FIG. 2. In the following embodiments, the word lines WLn−2, WLn−1, WLn+1, and WLn+2 will be described as being considered program non-selected word lines or read non-selected word lines. When one of the word lines WLn−2, WLn−1, WLn+1, WLn+2 is a target word line for a program operation or a read operation, a program voltage or a read voltage may be applied to the target word line instead of operation voltages described below.

Referring to FIG. 4A, according to a program method PM11, in a program interval, a first program pass voltage VPP1 may be applied to the word lines WLn−2, WLn−1, WLn+1, WLn+2 and the second intermediate dummy word line DWL2, and a second program pass voltage VPP2 less than the first program pass voltage VPP1 may be applied to the first intermediate dummy word line DWL1. The program interval may be an interval during which a program voltage for a program operation is applied to a target word line. The first and second program pass voltages VPP1, VPP2 may be less than the program voltage. For example, the first program pass voltage VPP1 may be 10V and the second program pass voltage VPP2 may be a range of 5V to 8V. Memory cells or intermediate dummy memory cells to which the first program pass voltage VPP1 or the second program pass voltage VPP2 is applied might not be programmed.

As a result, according to a program method PM11, compared to a program method PREF1 in which the first program pass voltage VPP1 is applied to all of the word lines WLn−2, WLn−1, WLn+1, WLn+2 and the first and second intermediate dummy word lines DWL1, DWL2, the boosting efficiency for program-inhibited bit lines may be maintained, while various issues such as device degradation and disturb on the first intermediate dummy memory cell DMC1 may be further alleviated.

Referring to FIG. 4B, according to an erase method EM11, in an erase interval, a first gate voltage VG1 may be applied to the word lines WLn−2, WLn−1, WLn+1, WLn+2 and the second intermediate dummy word line DWL2, and the first intermediate dummy word line DWL1 may be floated. The erase interval may be an interval during which an erase voltage VERS is applied to a channel of the string ST1 through the source line SL or the bit line BL. For example, the erase voltage VERS may be 18V and the first gate voltage VG1 may be 0V. The first intermediate dummy memory cell DMC1 might not be erased in the erase method EM11 because it is not used for data storage.

According to an erase method EM12, in an erase interval, the first gate voltage VG1 may be applied to the word lines WLn−2, WLn−1, WLn+1, WLn+2 and the second intermediate dummy word line DWL2, and a second gate voltage VG2 greater than the first gate voltage VG1 may be applied to the first intermediate dummy word line DWL1. For example, the second gate voltage VG2 may be a range of 1V to 2V. Thus, the potential difference between the first intermediate dummy word line DWL1 and the source line SL can be reduced.

As a result, according to the erase methods EM11, EM12, various issues such as device degradation and disturb on the first intermediate dummy memory cell DMC1 may be further alleviated compared to an erase method EREF1 in which the first gate voltage VG1 is applied to both the word lines WLn−2, WLn−1, WLn+1, WLn+2 and the first and second intermediate dummy word lines DWL1, DWL2.

Referring to FIG. 4C, according to a read method RM11, in a read interval, a first read pass voltage VRP1 may be applied to the word lines WLn−2, WLn−1, WLn+1, WLn+2 and the second intermediate dummy word line DWL2, and a second read pass voltage VRP2 less than the first read pass voltage VRP1 may be applied to the first intermediate dummy word line DWL1. The read interval may be an interval during which a read voltage is applied to a target word line of a read operation. The first and second read pass voltages VRP1, VRP2 may be greater than the read voltage. For example, the first read pass voltage VRP1 may be 7V and the second read pass voltage VRP2 may be a range of 1V to 6V. The first and second read pass voltages VRP1, VRP2 may be voltages that can turn on a memory cell or an intermediate dummy memory cell. The first intermediate dummy memory cell DMC1 may have a low threshold voltage because it is not used for data storage, and thus may allow current to flow properly through a channel of the string ST1 even when the second read pass voltage VRP2 with a low level is applied.

According to a read method RM12, in a read interval, the second read pass voltage VRP2 is applied to the first intermediate dummy word line DWL1, a third read pass voltage VRP3 greater than the first read pass voltage VRP1 is applied to a neighboring word line WLn−1 and the second intermediate dummy word line DWL2 adjacent to the first intermediate dummy word line DWL1, and the first read pass voltage VRP1 may be applied to the word lines WLn−2, WLn+1, WLn+2. For example, the third read pass voltage VRP3 may have a range of 8V to 9V. Thus, the third read pass voltage VRP3 with a high level may cause an increase in the fringing field to compensate for the decrease in electric field caused by the second read pass voltage VRP2 with a low level, thereby allowing proper flow of current through a channel of the string ST1.

As a result, according to the read methods RM11, RM12, various issues such as device degradation and disturb on the first intermediate dummy memory cell DMC1 may be further alleviated compared to a read method RREF1 in which the first read pass voltage VRP1 is applied to all of the word lines WLn−2, WLn−1, WLn+1, WLn+2 and the first and second intermediate dummy word lines DWL1, DWL2.

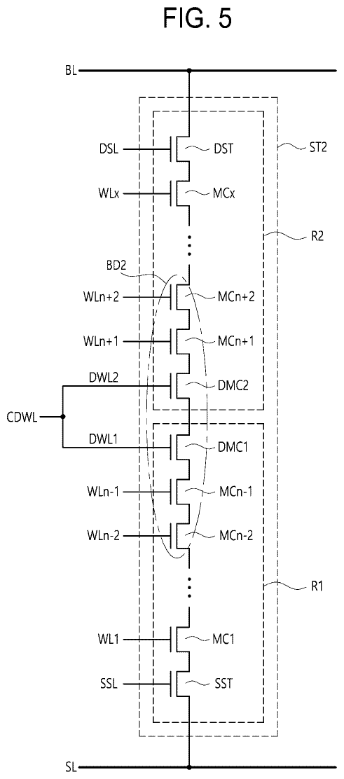

FIG. 5 is a diagram illustrating a string ST2 according to an embodiment of the present disclosure.

Referring to FIG. 5, the first intermediate dummy word line DWL1 and the second intermediate dummy word line DWL2 may be coupled to a common intermediate dummy word line CDWL. The decoder 123 of FIG. 1 may be coupled to the common intermediate dummy word line CDWL, and may apply an operating voltage to the common intermediate dummy word line CDWL. The first intermediate dummy word line DWL1 and the second intermediate dummy word line DWL2 may be applied with an operating voltage through the common intermediate dummy word line CDWL. The other structure of the string ST2 may be similar to the structure of the string ST1 of FIG. 2. The other structure of the string ST2 may be similar to the structure of the string ST1 of FIG. 2. The string ST2 may include a boundary BD2. The structure of the boundary BD2 may be similar to the structure of the boundary BD1 of FIG. 2.

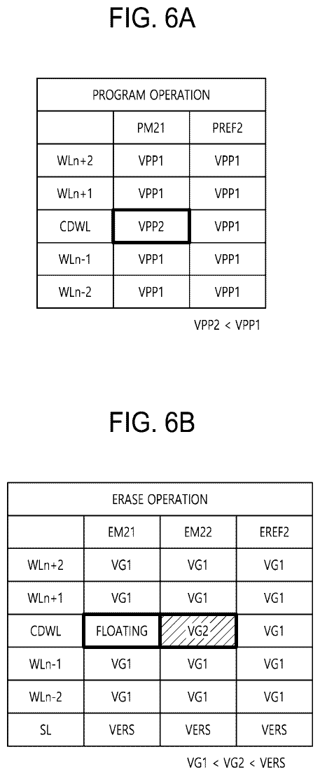

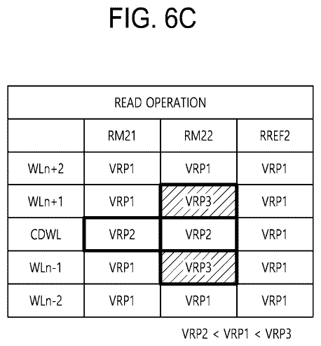

FIGS. 6A to 6C are diagrams illustrating operating voltages applied to the vicinity of the boundary BD2 of the string ST2 of FIG. 5.

Referring to FIG. 6A, according to a program method PM21, in a program interval, a first program pass voltage VPP1 may be applied to the word lines WLn−2, WLn−1, WLn+1, WLn+2, and a second program pass voltage VPP2 less than the first program pass voltage VPP1 may be applied to the common intermediate dummy word line CDWL. For example, the first program pass voltage VPP1 may be 10 V and the second program pass voltage VPP2 may have a range of 5V to 8V.

As a result, according to the program method PM21, compared to a program method PREF2 in which the first program pass voltage VPP1 is applied to all of the word lines WLn−2, WLn−1, WLn+1, WLn+2 and the common intermediate dummy word line CDWL, the boosting efficiency for program-prohibited bit lines may be maintained, while various issues such as device degradation and disturb to the first and second intermediate dummy memory cells DMC1, DMC2 may be further alleviated.

Referring to FIG. 6B, according to an erase method EM21, in an erase interval, a first gate voltage VG1 is applied to the word lines WLn−2, WLn−1, WLn+1, WLn+2, and the common intermediate dummy word line CDWL may be floated. For example, the erase voltage VERS may be 18V and the first gate voltage VG1 may be 0V. The first and second intermediate dummy memory cells DMC1, DMC2 might not be erased in the erase method EM21 because they are not used for data storage.

According to an erase method EM22, in an erase interval, the first gate voltage VG1 may be applied to the word lines WLn−2, WLn−1, WLn+1, WLn+2, and a second gate voltage VG2 greater than the first gate voltage VG1 may be applied to the common intermediate dummy word line CDWL. For example, the second gate voltage VG2 may have a range of 1V to 2V.

As a result, according to the erase methods EM21, EM22, compared to an erase method EREF2 in which the first gate voltage VG1 is applied to all of the word lines WLn−2, WLn−1, WLn+1, WLn+2 and the common intermediate dummy word line CDWL, because the potential difference between the common intermediate dummy word line CDWL and the source line SL is reduced, various issues such as device degradation and disturb on the first and second intermediate dummy memory cells DMC1, DMC2 may be further alleviated.

Referring to FIG. 6C, according to a read method RM21, in a read interval, a first read pass voltage VRP1 may be applied to the word lines WLn−2, WLn−1, WLn+1, WLn+2, and a second read pass voltage VRP2 less than the first read pass voltage VRP1 may be applied to the common intermediate dummy word line CDWL. For example, the first read pass voltage VRP1 may be 7V and the second read pass voltage VRP2 may have a range of 1V to 6V. Because the first and second intermediate dummy memory cells DMC1, DMC2 are not used for data storage, they may have low threshold voltages, and thus allow current to flow appropriately through a channels of the string ST2 even when the second read pass voltage VRP2 with a low level is applied.

According to a read method RM22, in a read interval, the second read pass voltage VRP2 may be applied to the common intermediate dummy word line CDWL, a third read pass voltage VRP3 greater than the first read pass voltage VRP1 may be applied to neighboring word lines WLn−1, WLn+1 adjacent to the common intermediate dummy word line CDWL, and the first read pass voltage VRP1 may be applied to the word lines WLn−2, WLn+2. For example, the third read pass voltage VRP3 may have a range of 8V to 9V. Thus, the third read pass voltage VRP3 with a high level may cause an increase in the fringing field to compensate for the decrease in electric field caused by the second read pass voltage VRP2 with a low level, thereby allowing proper flow of current through a channel of the string ST2.

As a result, according to the read methods RM21, RM22, various stresses such as device degradation and disturb on the first and second intermediate dummy memory cells DMC1, DMC2 may be further alleviated compared to a read method RREF2 in which the first read pass voltage VRP1 is applied to all of the word lines WLn−2, WLn−1, WLn+1, WLn+2 and the common intermediate dummy word line CDWL.

In an embodiment, the operating voltages shown in FIGS. 6A to 6C may be similarly applied to the string ST1 of FIG. 2. The operating voltage applied to the common intermediate dummy word line CDWL in FIGS. 6A to 6C may be applied to the first and second intermediate dummy word lines DWL1, DWL2 of FIG. 2, respectively.

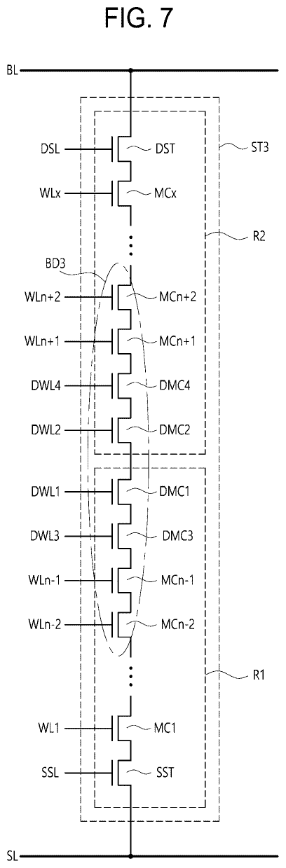

FIG. 7 a diagram illustrating a string ST3 according to an embodiment of the present disclosure.

Referring to FIG. 7, a third intermediate dummy memory cell DMC3 may be further coupled between the first intermediate dummy memory cell DMC1 and the memory cell MCn−1. The third intermediate dummy memory cell DMC3 may be coupled to a third intermediate dummy word line DWL3. Then, a fourth intermediate dummy memory cell DMC4 may be further coupled between the second intermediate dummy memory cell DMC2 and the memory cell MCn+1. The fourth intermediate dummy memory cell DMC4 may be coupled to a fourth intermediate dummy word line DWL4.

The first region R1 and the second region R2 may include a boundary BD3. The vicinity of the boundary BD3 may include the first, second, third, and fourth intermediate dummy memory cells DMC1, DMC2, DMC3, and DMC4 and neighboring memory cells adjacent to the third and fourth intermediate dummy memory cells DMC3 and DMC4 (e.g., MCn−2, MCn−1, MCn+1, MCn+2). The number of neighboring memory cells shown as being included in the vicinity of the boundary BD3 are illustrated as an example and other numbers of neighboring memory cells may be used. The other structure of the string ST3 may be similar to the structure of the string ST1 of FIG. 2.

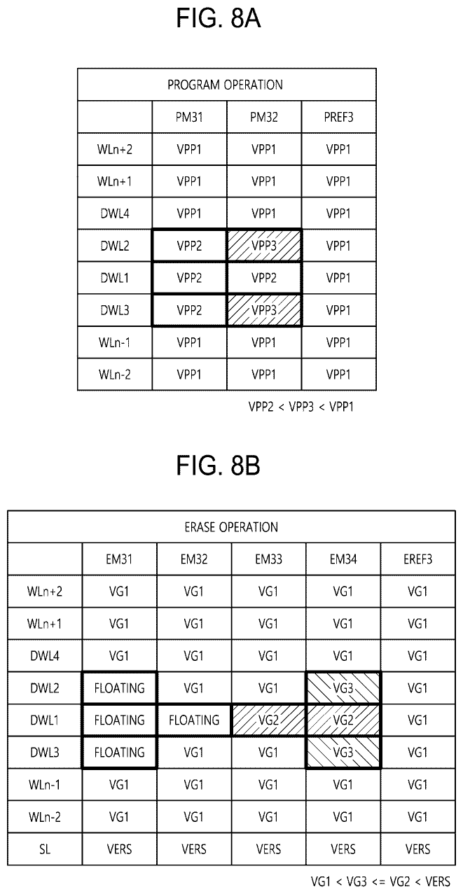

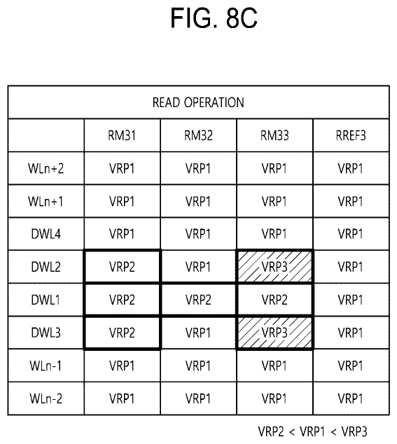

FIGS. 8A to 8C are diagrams illustrating operating voltages applied to the vicinity of the boundary BD3 of the string ST3 of FIG. 7.

Referring to FIG. 8A, according to a program method PM31, in a program interval, a first program pass voltage VPP1 may be applied to the word lines WLn−2, WLn−1, WLn+1, WLn+2, and the fourth intermediate dummy word line DWL4, and a second program pass voltage VPP2 less than the first program pass voltage VPP1 may be applied to the first, second, and third intermediate dummy word lines DWL1, DWL2, DWL3. For example, the first program pass voltage VPP1 may be 10V and the second program pass voltage VPP2 may have a range of 5V to 8V.

According to a program method PM32, in a program interval, the first program pass voltage VPP1 is applied to the word lines WLn−2, WLn−1, WLn+1, WLn+2, and the fourth intermediate dummy word line DWL4, the second program pass voltage VPP2 is applied to the first intermediate dummy word line DWL1, and a third program pass voltage VPP3 greater than the second program pass voltage VPP2 and less than the first program pass voltage VPP1 may be applied to the second and third intermediate dummy word lines DWL2, DWL3. For example, the third program pass voltage VPP3 may be 9V. Thus, the voltage may change gradually in the vicinity of the first intermediate dummy word line DWL1 such that disturb caused by hot carrier injection may be suppressed.

As a result, according to the program methods PM31, PM32, compared to a program method PREF3 in which the first program pass voltage VPP1 is applied to all of the word lines WLn−2, WLn−1, WLn+1, WLn+2 and the first to fourth intermediate dummy word lines DWL1 to DWL4, the boosting efficiency for program-prohibited bit lines is maintained, while various issues such as device degradation and disturb on the first intermediate dummy memory cell DMC1 may be further alleviated.

Referring to FIG. 8B, according to an erase method EM31, in an erase interval, a first gate voltage VG1 is applied to the word lines WLn−2, WLn−1, WLn+1, WLn+2 and the fourth intermediate dummy word line DWL4, and the first, second, and third intermediate dummy word lines DWL1, DWL2, DWL3 may be floated. For example, the erase voltage VERS may be 18V and the first gate voltage VG1 may be 0V. The first, second, and third intermediate dummy memory cells DMC1, DMC2, and DMC3 might not be erased in the erase method EM31 because they are not used for data storage.

According to an erase method EM32, in an erase interval, the first gate voltage VG1 is applied to the word lines WLn−2, WLn−1, WLn+1, WLn+2 and the second, third, and fourth intermediate dummy word lines DWL2, DWL3, DWL4, and the first intermediate dummy word line DWL1 may be floated. Because the first intermediate dummy memory cell DMC1 is not used for data storage, it might not be erased in the erase method EM32.

According to an erase method EM33, in an erase interval, the first gate voltage VG1 may be applied to the word lines WLn−2, WLn−1, WLn+1, WLn+2 and the second, third, and fourth intermediate dummy word lines DWL2, DWL3, DWL4, and a second gate voltage VG2 greater than the first gate voltage VG1 may be applied to the first intermediate dummy word line DWL1. For example, the second gate voltage VG2 may have a range of 1V to 2V. Accordingly, the potential difference between the first intermediate dummy word line DWL1 and the source line SL may be reduced. Because the third and fourth intermediate dummy memory cells DMC3, DMC4 are normal, applying the first gate voltage VG1 does not cause deterioration due to the erase voltage VERS, and the erase speed of the neighboring memory cells MCn−1, MCn+1 can be maintained by applying the first gate voltage VG1.

According to an erase method EM34, in an erase interval, the first gate voltage VG1 is applied to the word lines WLn−2, WLn−1, WLn+1, WLn+2 and the fourth intermediate dummy word line DWL4, a third gate voltage VG3 greater than the first gate voltage VG1 is applied to the second and third intermediate dummy word lines DWL2, DWL3, and a second gate voltage VG2 greater than or equal to the third gate voltage VG3 is applied to the first intermediate dummy word line DWL1. For example, the third gate voltage VG3 may be 1V. Thus, the potential difference between the first intermediate dummy word line DWL1 and the source line SL may be reduced. Further, the voltage may change gradually in the vicinity of the first intermediate dummy word line DWL1 such that disturb caused by hot carrier injection may be suppressed.

As a result, according to the erase methods EM31 to EM34, various issues such as device degradation and disturb on the first intermediate dummy memory cell DMC1 may be further alleviated compared to an erase method EREF3 in which the first gate voltage VG1 is applied to all of the word lines WLn−2, WLn−1, WLn+1, WLn+2 and the first to fourth intermediate dummy word lines DWL1 to DWL4.

Referring to FIG. 8C, according to a read method RM31, in a read interval, a first read pass voltage VRP1 may be applied to the word lines WLn−2, WLn−1, WLn+1, WLn+2 and the fourth intermediate dummy word line DWL4, and a second read pass voltage VRP2 less than the first read pass voltage VRP1 may be applied to the first, second, and third intermediate dummy word lines DWL1, DWL2, DWL3. For example, the first read pass voltage VRP1 may be 7V and the second read pass voltage VRP2 may have a range of 1V to 6V. Because the first intermediate dummy memory cell DMC1 is not used for data storage, it may have a low threshold voltage, and therefore, current may flow appropriately through a channel of the string ST3 even when the second read pass voltage VRP2 with a low level is applied.

According to a read method RM32, in a read interval, the first read pass voltage VRP1 may be applied to the word lines WLn−2, WLn−1, WLn+1, WLn+2 and the second, third, and fourth intermediate dummy word lines DWL2, DWL3, DWL4, and the second read pass voltage VRP2 may be applied to the first intermediate dummy word line DWL1. Because the first intermediate dummy memory cell DMC1 is not used for data storage, it may have a low threshold voltage, and therefore, current may flow appropriately through a channel of the string ST3 even when the second read pass voltage VRP2 with a low level is applied.

According to a read method RM33, in a read interval, the second read pass voltage VRP2 is applied to the first intermediate dummy word line DWL1, a third read pass voltage VRP3 greater than the first read pass voltage VRP1 is applied to the second and third intermediate dummy word lines DWL2, DWL3 adjacent to the first intermediate dummy word line DWL1, and the first read pass voltage VRP1 may be applied to the other word lines WLn−2, WLn−1, WLn+1, WLn+2 and the fourth intermediate dummy word line DWL4. For example, the third read pass voltage VRP3 may have a range of 8V to 9V. Thus, the third read pass voltage VRP3 with a high level may cause an increase in the fringing field to compensate for the decrease in electric field caused by the second read pass voltage VRP2 with a low level, thereby allowing proper flow of current through a channel of the string ST3.

As a result, according to the read methods RM31 to RM33, various issues such as device degradation and disturb on the first intermediate dummy memory cell DMC1 may be further alleviated compared to a read method RREF3 in which the first read pass voltage VRP1 is applied to all of the word lines WLn−2, WLn−1, WLn+1, WLn+2 and the first to fourth intermediate dummy word lines DWL1 to DWL4.

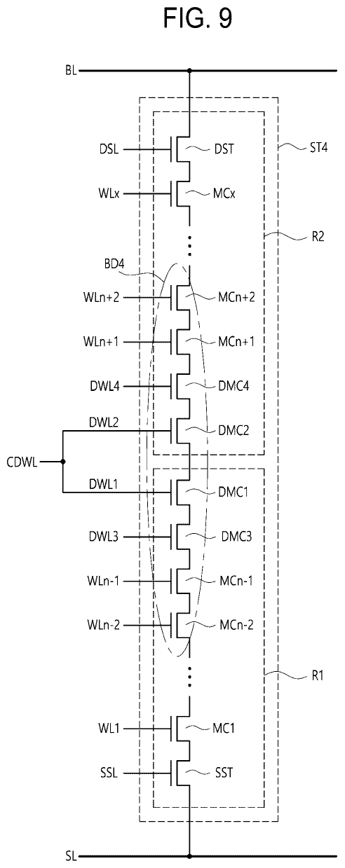

FIG. 9 is a diagram illustrating a string ST4 according to an embodiment of the present disclosure.

Referring to FIG. 9, the first intermediate dummy word line DWL1 and the second intermediate dummy word line DWL2 may be coupled to a common intermediate dummy word line CDWL. The decoder 123 of FIG. 1 may be coupled to the common intermediate dummy word line CDWL, and may apply an operating voltage to the common intermediate dummy word line CDWL. The first intermediate dummy word line DWL1 and the second intermediate dummy word line DWL2 may be applied an operating voltage through the common intermediate dummy word line CDWL. The other structure of the string ST4 may be similar to the structure of the string ST3 of FIG. 7. The string ST4 may include a boundary BD4. The structure of the boundary BD4 may be similar to the structure of the boundary BD3 of FIG. 7.

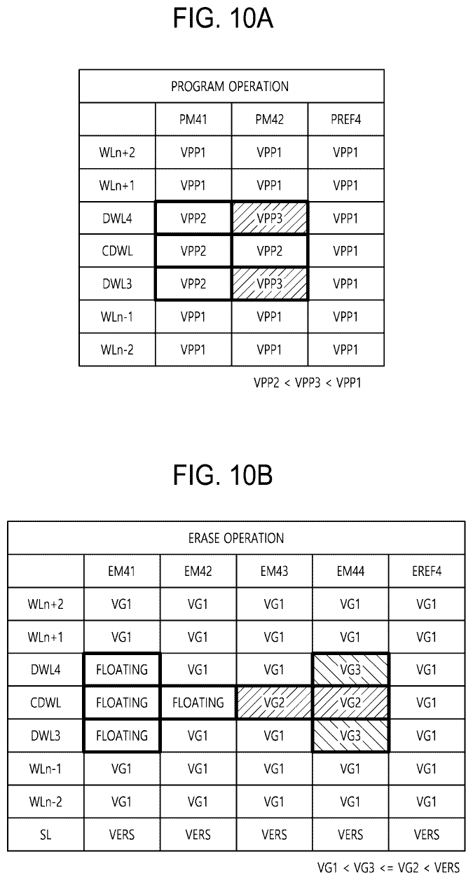

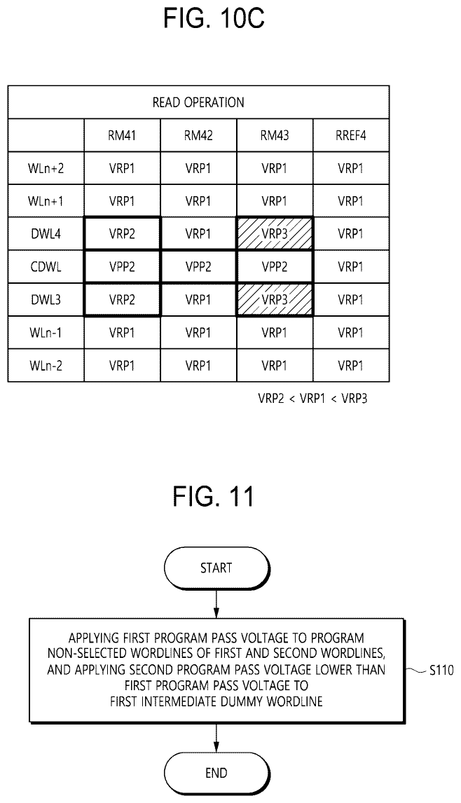

FIGS. 10A to 10C are diagrams illustrating operating voltages applied to the vicinity of the boundary BD4 of the string ST4 of FIG. 9.

Referring to FIG. 10A, according to a program method PM41, in a program interval, a first program pass voltage VPP1 may be applied to the word lines WLn−2, WLn−1, WLn+1, WLn+2, and a second program pass voltage VPP2 less than the first program pass voltage VPP1 may be applied to the common intermediate dummy word line CDWL and the third and fourth intermediate dummy word lines DWL3, DWL4. For example, the first program pass voltage VPP1 may be 10V and the second program pass voltage VPP2 may have a range of 5V to 8V.

According to a program method PM42, in a program interval, the first program pass voltage VPP1 may be applied to the word lines WLn−2, WLn−1, WLn+1, WLn+2, the second program pass voltage VPP2 may be applied to the common intermediate dummy word line CDWL, and a third program pass voltage VPP3 that is greater than the second program pass voltage VPP2 and less than the first program pass voltage VPP1 may be applied to the third and fourth intermediate dummy word lines DWL3, DWL4. For example, the third program pass voltage VPP3 may be 9V. Thus, the voltage may change gradually in the vicinity of the common intermediate dummy word line CDWL such that disturb caused by hot carrier injection may be suppressed.

As a result, according to the program methods PM41, PM42, compared to a programming method PREF4 in which the first program pass voltage VPP1 is applied to the word lines WLn−2, WLn−1, WLn+1, WLn+2, the common intermediate dummy word line CDWL, and the third and fourth intermediate dummy word lines DWL3, DWL4, the boosting efficiency for program-prohibited bit lines is maintained, while various issues such as device degradation and disturb on the first and second intermediate dummy memory cells DMC1, DMC2 may be further alleviated.

Referring to FIG. 10B, according to an erase method EM41, in an erase interval, a first gate voltage VG1 is applied to the word lines WLn−2, WLn−1, WLn+1, WLn+2, and the common intermediate dummy word line CDWL and the third and fourth intermediate dummy word lines DWL3, DWL4 may be floated. For example, the erase voltage VERS may be 18V and the first gate voltage VG1 may be 0V. The first to fourth intermediate dummy memory cells DMC1 to DMC4 might not be erased in the erase method EM41 because they are not used for data storage.

According to an erase method EM42, in an erase interval, the first gate voltage VG1 is applied to the word lines WLn−2, WLn−1, WLn+1, WLn+2 and the third and fourth intermediate dummy word lines DWL3, DWL4, and the common intermediate dummy word line CDWL may be floated. The first and second intermediate dummy memory cells DMC1, DMC2 are not used for data storage and might not be erased in the erase method EM42.

According to an erase method EM43, in an erase interval, the first gate voltage VG1 may be applied to the word lines WLn−2, WLn−1, WLn+1, WLn+2 and the third and fourth intermediate dummy word lines DWL3, DWL4, and a second gate voltage VG2 greater than the first gate voltage VG1 may be applied to the common intermediate dummy word line CDWL. For example, the second gate voltage VG2 may have a range of 1V to 2V. Accordingly, the potential difference between the common intermediate dummy word line CDWL and the source line SL may be reduced. Because the third and fourth intermediate dummy memory cells DMC3, DMC4 are normal, the first gate voltage VG1 might not cause degradation due to the erase voltage VERS even when the first gate voltage VG1 is applied, and the erase speed of the neighboring memory cells may be maintained by applying the first gate voltage VG1.

According to an erase method EM44, in an erase interval, the first gate voltage VG1 may be applied to the word lines WLn−2, WLn−1, WLn+1, WLn+2, a third gate voltage VG3 greater than the first gate voltage VG1 may be applied to the third and fourth intermediate dummy word lines DWL3, DWL4, and a second gate voltage VG2 greater than or equal to the third gate voltage VG3 may be applied to the common intermediate dummy word line CDWL. For example, the third gate voltage VG3 may be 1V. Accordingly, the potential difference between the common intermediate dummy word line CDWL and the source line SL may be reduced. Furthermore, the voltage may change gradually in the vicinity of the common intermediate dummy word line CDWL such that disturb caused by hot carrier injection may be suppressed.

As a result, according to the erase methods EM41 to EM44, various issues such as device degradation and disturb on the first and second intermediate dummy memory cells DMC1, DMC2 may be further alleviated compared to an erase method EREF4 in which the first gate voltage VG1 is applied to the word lines WLn−2, WLn−1, WLn+1, WLn+2, the common intermediate dummy word line CDWL, and the third and fourth intermediate dummy word lines DWL3, DWL4.

Referring to FIG. 10C, according to a read method RM41, in a read interval, a first read pass voltage VRP1 may be applied to the word lines WLn−2, WLn−1, WLn+1, WLn+2, and a second read pass voltage VRP2 less than the first read pass voltage VRP1 may be applied to the common intermediate dummy word line CDWL and the third and fourth intermediate dummy word lines DWL3, DWL4. For example, the first read pass voltage VRP1 may be 7V and the second read pass voltage VRP2 may have a range of 1V to 6V. Because the first to fourth intermediate dummy memory cells DMC1 to DMC4 are not used for data storage, they may have low threshold voltages, and thus allow current to flow appropriately through a channel of the string ST4 even when the second read pass voltage VRP2 with a low level is applied.

According to a read method RM42, in a read interval, the first read pass voltage VRP1 may be applied to the word lines WLn−2, WLn−1, WLn+1, WLn+2 and the third and fourth intermediate dummy word lines DWL3, DWL4, and the second read pass voltage VRP2 may be applied to the common intermediate dummy word line CDWL. Because the first and second intermediate dummy memory cells DMC1, DMC2 are not used for data storage, they may have low threshold voltages and, therefore, allow current to flow properly through a channel of the string ST4 even when the second read pass voltage VRP2 with a low level is applied.

According to a read method RM43, in a read interval, the first read pass voltage VRP1 may be applied to the word lines WLn−2, WLn−1, WLn+1, WLn+2, the second read pass voltage VRP2 may be applied to the common intermediate dummy word line CDWL, and a third read pass voltage VRP3 that is greater than the first read pass voltage VRP1 may be applied to the third and fourth intermediate dummy word lines DWL3, DWL4. For example, the third read pass voltage VRP3 may have a range of 8V to 9V. Thus, the third read pass voltage VRP3 with a high level may cause an increase in the fringing field to compensate for the decrease in electric field caused by the second read pass voltage VRP2 with a low level, thereby allowing proper flow of current through a channel of the string ST4.

As a result, according to the read methods RM41 to RM43, various issues such as device degradation and disturb on the first and second intermediate dummy memory cells DMC1, DMC2 may be further alleviated compared to a read method RREF4 in which the first read pass voltage VRP1 is applied to the word lines WLn−2, WLn−1, WLn+1, WLn+2, the common intermediate dummy word line CDWL, and the third and fourth intermediate dummy word lines DWL3, DWL4.

In an embodiment, the operating voltages shown in FIGS. 10A to 10C may be similarly applied to the string ST3 of FIG. 7. Specifically, the operating voltage applied to the common intermediate dummy word line CDWL in FIGS. 10A to 10C may be applied to the first and second intermediate dummy word lines DWL1, DWL2 of FIG. 7, respectively. The operating voltages applied to the third and fourth intermediate dummy word lines DWL3, DWL4 in FIGS. 10A to 10C may be applied to the third and fourth intermediate dummy word lines DWL3, DWL4 of FIG. 7, respectively.

In an embodiment, by stacking three or more plugs, each string may further include one or more regions stacked between the first region R1 and the second region R2. Each of the intermediate regions may include a lower intermediate dummy memory cell similar to the second intermediate dummy memory cell DMC2 at the bottom, an upper intermediate dummy memory cell similar to the first intermediate dummy memory cell DMC1 at the top, and memory cells coupled between the lower intermediate dummy memory cell and the upper intermediate dummy memory cell. The structures in the vicinity of the boundaries between the first region R1, the intermediate regions, and the second region R2 may be configured similarly to the structures in the vicinity of the boundaries BD1, BD2, BD3, or BD4 of FIG. 2, FIG. 5, FIG. 7, or FIG. 9. Among a plurality of regions within each string, the lower region of adjacent regions may be treated in a manner similar to the first region R1, while the upper region may be managed similar to the second region R2. The control circuit 110 and the peripheral circuit 120 may control the vicinity of each boundary between the plurality of regions similar to the manner described with reference to FIGS. 4A to 4C, FIGS. 6A to 6C, FIGS. 8A to 8C, and FIGS. 10A to 10C.

FIG. 11 is a flowchart illustrating a method of operating of the memory device 100 according to an embodiment of the present disclosure.

Referring to FIG. 11, in operation S110, the memory device 100 may apply a first program pass voltage to program non-selected word lines of first word lines coupled to first memory cells of a string and second word lines coupled to second memory cells of the string in a program interval, and a second program pass voltage less than the first program pass voltage to a first intermediate dummy word line coupled to a first intermediate dummy memory cell of first and second intermediate dummy memory cells coupled between the first and second memory cells of the string.

In an embodiment, the method of operating the memory device 100 may further include, in a program interval, applying the first program pass voltage to the second intermediate dummy word line.

In an embodiment, the method of operating the memory device 100 may further include, in an erase interval, applying a first gate voltage to the first and second word lines and the second intermediate dummy word line, and floating the first intermediate dummy word line.

In an embodiment, the method of operating the memory device 100 may further include, in an erase interval, applying a first gate voltage to the first and second word lines and the second intermediate dummy word line, and applying a second gate voltage higher than the first gate voltage to the first intermediate dummy word line.

In an embodiment, the method of operating the memory device 100 may further include, in a read interval, applying a first read pass voltage to read non-selected word lines of the first and second word lines and the second intermediate dummy word line, and applying a second read pass voltage less than the first read pass voltage to the first intermediate dummy word line.

In an embodiment, the method of operating the memory device 100 may further include, in a read interval, applying a first read pass voltage to read non-selected word lines excluding a first neighboring word line of the first and second word lines, applying a second read pass voltage less than the first read pass voltage to the first intermediate dummy word line, applying a third read pass voltage greater than the first read pass voltage to the second intermediate dummy word line, and applying the third read pass voltage greater than the first read pass voltage to the first neighboring word line when it is determined that the first neighboring word line is not a read target word line. The first neighboring word line may be coupled to a first neighboring memory cell adjacent to the first intermediate dummy memory cell of the first memory cells.

In an embodiment, the method of operating the memory device 100 may further include, in a program interval, applying a second program pass voltage to a common intermediate dummy word line to which the first and second intermediate dummy word lines are coupled in common.

In an embodiment, the method of operating the memory device 100 may further include, in an erase interval, applying a first gate voltage to the first and second word lines, and floating a common intermediate dummy word line to which the first and second intermediate dummy word lines are coupled in common.

In an embodiment, the method of operating the memory device 100 may further include, in an erase interval, applying a first gate voltage to the first and second word lines, and applying a second gate voltage greater than the first gate voltage to a common intermediate dummy word line to which the first and second intermediate dummy word lines are coupled in common.

In an embodiment, the method of operating the memory device 100 may further include, in a read interval, applying a first read pass voltage to read non-selected word lines of the first and second word lines, and applying a second read pass voltage less than the first read pass voltage to a common intermediate dummy word line to which the first and second intermediate dummy word lines are coupled in common.

In an embodiment, the method of operating the memory device 100 may further include, in a read interval, applying a first read pass voltage to read non-selected word lines excluding first and second neighboring word lines, applying a second read pass voltage less than the first read pass voltage to a common intermediate dummy word line to which the first and second intermediate dummy word lines are coupled in common, and applying a third read pass voltage greater than the first read pass voltage to the first and second neighboring word lines when it is determined that each of the first and second neighboring word lines is not a read target word line. The first neighboring word line may be coupled to a first neighboring memory cell adjacent to a first intermediate dummy memory cell of the first memory cells. The second neighboring word line may be coupled to a second neighboring memory cell adjacent to a second intermediate dummy memory cell of the second memory cells.

In an embodiment, the method of operating the memory device 100 may further include controlling a third intermediate dummy word line coupled to a third intermediate dummy memory cell coupled in series between the first intermediate dummy memory cell and the first memory cells, and controlling a fourth intermediate dummy word line coupled to a fourth intermediate dummy memory cell coupled in series between the second intermediate dummy memory cell and the second memory cells.

In an embodiment, the method of operating the memory device 100 may further include, in a program interval, applying a first program pass voltage to the fourth intermediate dummy word line and applying a second program pass voltage to the second and third intermediate dummy word lines.

In an embodiment, the method of operating the memory device 100 may further include, in a program interval, applying a first program pass voltage to the fourth intermediate dummy word line, and applying a third program pass voltage that is greater than the second program pass voltage and less than the first program pass voltage to the second and third intermediate dummy word lines.

In an embodiment, the method of operating the memory device 100 may further include, in an erase interval, applying a first gate voltage to the first and second word lines and the fourth intermediate dummy word line, and floating the first, second, and third intermediate dummy word lines.

In an embodiment, the method of operating the memory device 100 may further include, in an erase interval, applying a first gate voltage to the first and second word lines and the second, third, and fourth intermediate dummy word lines, and floating the first intermediate dummy word line.

In an embodiment, the method of operating the memory device 100 may further include, in an erase interval, applying a first gate voltage to the first and second word lines and the second, third, and fourth intermediate dummy word lines, and applying a second gate voltage greater than the first gate voltage to the first intermediate dummy word line.

In an embodiment, the method of operating the memory device 100 may further include, in an erase interval, applying a first gate voltage to the first and second word lines and the fourth intermediate dummy word line, applying a second gate voltage that is higher than the first gate voltage to the first intermediate dummy word line, and applying a third gate voltage that is greater than the first gate voltage and less than or equal to the second gate voltage to the second and third intermediate dummy word lines.

In an embodiment, the method of operating the memory device 100 may further include, in a read interval, applying a first read pass voltage to read non-selected word lines of the first and second word lines and the fourth intermediate dummy word line, and applying a second read pass voltage less than the first read pass voltage to the first, second, and third intermediate dummy word lines.

In an embodiment, the method of operating the memory device 100 may further include, in a read interval, applying a first read pass voltage to read non-selected word lines of the first and second word lines and the second, third, and fourth intermediate dummy word lines, and applying a second read pass voltage less than the first read pass voltage to the first intermediate dummy word line.

In an embodiment, the method of operating the memory device 100 may further include, in a read interval, applying a first read pass voltage to read non-selected word lines of the first and second word lines and the fourth intermediate dummy word line, applying a second read pass voltage less than the first read pass voltage to the first intermediate dummy word line, and applying a third read pass voltage greater than the first read pass voltage to the second and third intermediate dummy word lines.

In an embodiment, the method of operating the memory device 100 may further include, in a program interval, applying a second program pass voltage to a common intermediate dummy word line to which the first and second intermediate dummy word lines are coupled in common and the third and fourth intermediate dummy word lines.

In an embodiment, the method of operating the memory device 100 may further include, in a program interval, applying a second program pass voltage to a common intermediate dummy word line to which the first and second intermediate dummy word lines are coupled in common, and applying a third program pass voltage that is greater than the second program pass voltage and less than the first program pass voltage to the third and fourth intermediate dummy word lines.

In an embodiment, the method of operating the memory device 100 may further include, in an erase interval, applying a first gate voltage to the first and second word lines, and floating a common intermediate dummy word line to which the first and second intermediate dummy word lines coupled in common, and the third and fourth intermediate dummy word lines.

In an embodiment, the method of operating the memory device 100 may further include, in an erase interval, applying a first gate voltage to the first and second word lines and the third and fourth intermediate dummy word lines, and floating a common intermediate dummy word line to which the first and second intermediate dummy word lines are coupled in common.

In an embodiment, the method of operating the memory device 100 may further include, in an erase interval, applying a first gate voltage to the first and second word lines and the third and fourth intermediate dummy word lines, and applying a second gate voltage higher than the first gate voltage to a common intermediate dummy word line to which the first and second intermediate dummy word lines are coupled in common.

In an embodiment, the method of operating the memory device 100 may further include, in an erase interval, applying a first gate voltage to the first and second word lines, applying a second gate voltage greater than the first gate voltage to a common intermediate dummy word line to which the first and second intermediate dummy word lines are coupled in common, and applying a third gate voltage greater than the first gate voltage and less than or equal to the second gate voltage to the third and fourth intermediate dummy word lines.

In an embodiment, the method of operating the memory device 100 may further include, in a read interval, applying a first read pass voltage to read non-selected word lines of the first and second word lines, and applying a second read pass voltage less than the first read pass voltage to a common intermediate dummy word line to which the first and second intermediate dummy word lines are coupled in common, and the third and fourth intermediate dummy word lines.

In an embodiment, the method of operating the memory device 100 may further include, in a read interval, applying a first read pass voltage to read non-selected word lines of the first and second word lines and the third and fourth intermediate dummy word lines, and applying a second read pass voltage less than the first read pass voltage to a common intermediate dummy word line to which the first and second intermediate dummy word lines are coupled in common.

In an embodiment, the method of operating the memory device 100 may further include, in a read interval, applying a first read pass voltage to read non-selected word lines of the first and second word lines, applying a second read pass voltage less than the first read pass voltage to a common intermediate dummy word line to which the first and second intermediate dummy word lines are coupled in common, and applying a third read pass voltage greater than the first read pass voltage to the third and fourth intermediate dummy word lines.

The embodiments disclosed in the present disclosure should be considered from an illustrative standpoint and not a restrictive standpoint. Those skilled in the art will understand that various modifications, additions, combinations, and substitutions are possible without departing from the scope and technical concepts of the present disclosure. Therefore, the scope of the present disclosure is not limited to the provided descriptions. All changes within the meaning and range of equivalency of the claims should be included within their scope. Furthermore, the embodiments may be combined to form additional embodiments.

What is claimed is:

1. An operating method of a memory device, the method comprising:
in a program operation,
applying a first program pass voltage to program non-selected word lines of first word lines and second word lines, the first and second word lines coupled to first memory cells and second memory cells of a string, respectively; and
applying a second program pass voltage to a first intermediate dummy word line coupled to a first intermediate dummy memory cell, among the first intermediate dummy memory cell and a second intermediate dummy memory cell coupled to the first intermediate dummy word line and a second intermediate dummy word line, respectively, between the first memory cells and the second memory cells in the string, wherein the second program pass voltage is less than the first program pass voltage.

2. The method of claim 1, further comprising applying, in the program operation, the first program pass voltage to the second intermediate dummy word line.

3. The method of claim 1, further comprising: in an erase operation, applying a first gate voltage to the first and second word lines and the second intermediate dummy word line, and floating the first intermediate dummy word line.

4. The method of claim 1, further comprising: in an erase operation, applying a first gate voltage to the first and second word lines and the second intermediate dummy word line, and applying a second gate voltage to the first intermediate dummy word line, wherein the second gate voltage is greater than the first gate voltage.

5. The method of claim 1, further comprising: in a read operation, applying a first read pass voltage to read non-selected word lines of the first and second word lines and the second intermediate dummy word line, and applying a second read pass voltage to the first intermediate dummy word line, wherein the second read pass voltage is less than the first read pass voltage.

6. The method of claim 1, further comprising: in a read operation, applying a first read pass voltage to read non-selected word lines excluding a first neighboring word line of the first and second word lines, applying a second read pass voltage to the first intermediate dummy word line, applying a third read pass voltage to the second intermediate dummy word line, and applying the third read pass voltage to the first neighboring word line when it is determined that the first neighboring word line is not a read target word line,
wherein the second read pass voltage is less than the first read pass voltage, and the third read pass voltage is greater than the first read pass voltage, and
wherein the first neighboring word line is coupled to a first neighboring memory cell adjacent to the first intermediate dummy memory cell of the first memory cells.

7. The method of claim 1, further comprising: in the program operation, applying the second program pass voltage to a common intermediate dummy word line to which the first and second intermediate dummy word lines are coupled in common.

8. The method of claim 1, further comprising: in an erase operation, applying a first gate voltage to the first and second word lines, and floating a common intermediate dummy word line to which the first and second intermediate dummy word lines are coupled in common.

9. The method of claim 1, further comprising: in an erase operation, applying a first gate voltage to the first and second word lines, and applying a second gate voltage to a common intermediate dummy word line to which the first and second intermediate dummy word lines are coupled in common, wherein the second gate voltage is greater than the first gate voltage.

10. The method of claim 1, further comprising: in a read operation, applying a first read pass voltage to read non-selected word lines of the first and second word lines, and applying a second read pass voltage to a common intermediate dummy word line to which the first and second intermediate dummy word lines are coupled in common, wherein the second read pass voltage is less than the first read pass voltage.

11. The method of claim 1, further comprising: in a read operation, applying a first read pass voltage to read non-selected word lines excluding first and second neighboring word lines of the first and second word lines, applying a second read pass voltage to a common intermediate dummy word line to which the first and second intermediate dummy word lines are coupled in common, and applying a third read pass voltage to the first and second neighboring word lines when it is determined that each of the first and second neighboring word lines is not a read target word line,,
wherein the second read pass voltage is less than the first read pass voltage, and the third read pass voltage is greater than the first read pass voltage, and
wherein the first neighboring word line is coupled to a first neighboring memory cell adjacent to the first intermediate dummy memory cell of the first memory cells, and the second neighboring word line is coupled to a second neighboring memory cell adjacent to the second intermediate dummy memory cell of the second memory cells.

12. The method of claim 1, further comprising controlling a third intermediate dummy word line coupled to a third intermediate dummy memory cell coupled in series between the first intermediate dummy memory cell and the first memory cells, and controlling a fourth intermediate dummy word line coupled to a fourth intermediate dummy memory cell coupled in series between the second intermediate dummy memory cell and the second memory cells.

13. The method of claim 12, further comprising: in the program operation, applying the first program pass voltage to the fourth intermediate dummy word line, and applying the second program pass voltage to the second and third intermediate dummy word lines.

14. The method of claim 12, further comprising: in the program operation, applying the first program pass voltage to the fourth intermediate dummy word line, and applying a third program pass voltage to the second and third intermediate dummy word lines, wherein the third program pass voltage is greater than the second program pass voltage and is less than the first program pass voltage.

15. The method of claim 12, further comprising: in an erase operation, applying a first gate voltage to the first and second word lines and the fourth intermediate dummy word line, and floating the first, second, and third intermediate dummy word lines.

16. The method of claim 12, further comprising: in an erase operation, applying a first gate voltage to the first and second word lines and the second, third, and fourth intermediate dummy word lines, and floating the first intermediate dummy word line.

17. The method of claim 12, further comprising: in an erase operation, applying a first gate voltage to the first and second word lines and the second, third, and fourth intermediate dummy word lines, and applying a second gate voltage to the first intermediate dummy word line wherein the second gate voltage is greater than the first gate voltage.

18. The method of claim 12, further comprising: in an erase operation, applying a first gate voltage to the first and second word lines and the fourth intermediate dummy word line, applying a second gate voltage to the first intermediate dummy word line, and applying a third gate voltage to the second and third intermediate dummy word lines, wherein the second gate voltage is greater than the first gate voltage, and the third gate voltage is greater than the first gate voltage and less than or equal to the second gate voltage.

19. The method of claim 12, further comprising: in a read operation, applying a first read pass voltage to read non-selected word lines of the first and second word lines and the fourth intermediate dummy word line, and applying a second read pass voltage to the first, second, and third intermediate dummy word lines, wherein the second read pass voltage is less than the first read pass voltage.

20. The method of claim 12, further comprising: in a read operation, applying a first read pass voltage to read non-selected word lines of the first and second word lines and the second, third, and fourth intermediate dummy word lines, and applying a second read pass voltage to the first intermediate dummy word line, wherein the second read pass voltage is less than the first read pass voltage.

21. The method of claim 12, further comprising: in a read operation, applying a first read pass voltage to read non-selected word lines of the first and second word lines and the fourth intermediate dummy word line, applying a second read pass voltage to the first intermediate dummy word line, and applying a third read pass voltage to the second and third intermediate dummy word lines, wherein the second read pass voltage is less than the first read pass voltage, and the third read pass voltage is greater than the first read pass voltage.

22. The method of claim 12, further comprising: in the program operation, applying the second program pass voltage to a common intermediate dummy word line to which the first and second intermediate dummy word lines are coupled in common, and the third and fourth intermediate dummy word lines.

23. The method of claim 12, further comprising: in the program operation, applying the second program pass voltage to a common intermediate dummy word line to which the first and second intermediate dummy word lines are coupled in common, and applying a third program pass voltage to the third and fourth intermediate dummy word lines, wherein the third program pass voltage is greater than the second program pass voltage and less than the first program pass voltage.

24. The method of claim 12, further comprising: in an erase operation, applying a first gate voltage to the first and second word lines, and floating a common intermediate dummy word line to which the first and second intermediate dummy word lines are coupled in common, and the third and fourth intermediate dummy word lines.

25. The method of claim 12, further comprising: in an erase operation, applying a first gate voltage to the first and second word lines and the third and fourth intermediate dummy word lines, and floating a common intermediate dummy word line to which the first and second intermediate dummy word lines are coupled in common.

26. The method of claim 12, further comprising: in an erase operation, applying a first gate voltage to the first and second word lines and the third and fourth intermediate dummy word lines, and applying a second gate voltage to a common intermediate dummy word line to which the first and second intermediate dummy word lines are coupled in common, wherein the second gate voltage is greater than the first gate voltage.

27. The method of claim 12, further comprising: in an erase operation, applying a first gate voltage to the first and second word lines, applying a second gate voltage to a common intermediate dummy word line to which the first and second intermediate dummy word lines are coupled in common, and applying a third gate voltage to the third and fourth intermediate dummy word lines, wherein the second gate voltage is greater than the first gate voltage, and the third gate voltage is greater than the first gate voltage and less than or equal to the second gate voltage.

28. The method of claim 12, further comprising: in a read operation, applying a first read pass voltage to read non-selected word lines of the first and second word lines, and applying a second read pass voltage to a common intermediate dummy word line to which the first and second intermediate dummy word lines are coupled in common and the third and fourth intermediate dummy word lines, wherein the second read pass voltage is less than the first read pass voltage.

29. The method of claim 12, further comprising: in a read operation, applying a first read pass voltage to read non-selected word lines of the first and second word lines and the third and fourth intermediate dummy word lines, and applying a second read pass voltage to a common intermediate dummy word line to which the first and second intermediate dummy word lines are coupled in common, wherein the second read pass voltage is less than the first read pass voltage.

30. The method of claim 12, further comprising: in a read operation, applying a first read pass voltage to read non-selected word lines of the first and second word lines, applying a second read pass voltage to a common intermediate dummy word line to which the first and second intermediate dummy word lines are coupled in common, and applying a third read pass voltage to the third and fourth intermediate dummy word lines, wherein the second read pass voltage is less than the first read pass voltage, and the third read pass voltage is greater than the first read pass voltage.

31. A memory device comprising:
a string including a first region formed on a first plug and a second region formed on a second plug stacked on the first plug, the first region including a first intermediate dummy memory cell coupled to a first intermediate dummy word line and first memory cells coupled to first word lines, the second region including a second intermediate dummy memory cell coupled to a second intermediate dummy word line and second memory cells coupled to second word lines, the first and second intermediate dummy memory cells being adjacent to the first region and the second region, and the first and second intermediate dummy word lines being coupled to a common intermediate dummy word line;
a control circuit configured to control one or more operations on one or more memory cells of the string; and
a peripheral circuit configured to generate operating voltages for the one or more operations, and configured to apply the operating voltages to the first and second word lines and the common intermediate dummy word line.
